(19) United States
(12) Patent Application Publication
(10) Pub. No.: US 2003/0128592 A1
(43) Pub. Date: Jul. 10, 2003

(54) Semiconductor circuit configuration

(76) Inventor: Hermann Ruckerbauer, Moos (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/306,436

(22) Filed: Nov. 27, 2002

(30) Foreign Application Priority Data
Nov. 28, 2001 (DE) 101 58 271.4

(51) Int. Cl. G11C 5/00

(52) U.S. Cl. 365/189.01

(57) ABSTRACT

In order to be able to ensure the signal integrity in the simplest possible manner, both in the event of reading and in the event of writing, in the case of changing and rising transmission rates when a control device accesses at least one semiconductor circuit module, it is proposed that a termination impedance device that is provided for impedance matching with regard to the access by the control device to the semiconductor circuit modules provided is configured to be switchable between a plurality of impedance states.

### BACKGROUND OF THE INVENTION

1. Field of the Invention

The invention relates to a semiconductor circuit configuration having at least one semiconductor circuit module, a control device for accessing the semiconductor circuit module, and a main bus device with which the semiconductor circuit module is connected. The main bus has a first end region, which is connected to the control device, and a second region, which can be connected to or is connected to a termination potential via a termination contact. At least one termination impedance device is provided, which is configured in each case for impedance matching with regard to an access by the control device to the semiconductor circuit module.

In many semiconductor circuit configurations, at least one semiconductor circuit module that is provided is accessed via a control device. The access can be effected e.g. by the writing of data to the semiconductor circuit module or by the reading of data from the semiconductor circuit module. In order to realize the access, provision is furthermore made of a main bus device having a first end region and a second end region. The first end region is connected to the control device, and the second end region can be connected to or is connected to a termination potential via a termination contact.

When accessing the semiconductor circuit modules, which are connected to the main bus device in parallel, in particular, the problem arises that, in order to correctly identify the respective signals, the latter must not be distorted beyond a specific amount when traversing the entire semiconductor circuit configuration. In particular, it is necessary to avoid signal reflections in the region of the various junctions and line ends. This is achieved in a known manner by the provision of so-called termination impedance devices or termination resistors.

In this case, however, different values are necessary with regard to the respective terminating impedance, depending on the access, whether the latter is a reading or writing access. For this purpose, in a known manner, impedances that mediate as a compromise between these values are chosen at the line ends.

However, on account of the rising transmission rates and/or also owing to varying transmission rates on the lines and bus systems, reduced signal quality and signal integrities result on account of the excessively large impedance differences then occurring and can lead to operating problems in known semiconductor circuit configurations.

### SUMMARY OF THE INVENTION

It is accordingly an object of the invention to provide a semiconductor circuit configuration that overcomes the above-mentioned disadvantages of the prior art devices of this general type, in which it is possible to realize the signal integrity in a particularly simple yet reliable manner when a control device accesses the respective semiconductor circuit modules.

With the foregoing and other objects in view there is provided, in accordance with the invention, a semiconductor circuit configuration. The semiconductor device contains at least one semiconductor circuit module, a control device for accessing the semiconductor circuit module, a termination contact, and a main bus device having a first end region connected to the control device and a second end region connected to a termination potential though the termination contact. The main bus device is further connected to the semiconductor circuit module. At least one termination impedance device is provided for impedance matching with regard to an access by the control device to the semiconductor circuit module. The termination impedance device is switchable between a plurality of impedance states. The termination impedance device determining whether the control device effects a read access or a write access to the semiconductor circuit module and an impedance state can correspondingly be set automatically.

In the case of the semiconductor circuit configuration of the generic type, the at least one semiconductor circuit module is provided. Furthermore, the control device is provided, which is configured for accessing the semiconductor circuit module. For the access, provision is made of the main bus device having a first end region, which is connected to the control device, and a second end region, which can be connected to or is connected to a termination potential via a termination contact. The semiconductor circuit module is connected in parallel with the main bus device. Furthermore, at least one termination impedance device is provided, which is configured in each case for impedance matching with regard to the access by the control device to the respective semiconductor circuit module.

The semiconductor circuit configuration according to the invention is characterized in that the termination impedance device is configured to be switchable between a plurality of impedance states. What is thereby achieved according to the invention is that, depending on the mode of access of the control device to the respective semiconductor circuit modules, a corresponding impedance can be matched and selected, so that it is possible to achieve a maximum signal integrity in the case of the different modes of access of the control device to the semiconductor circuit modules. This is advantageous compared with the conventional procedure in which impedance values are prescribed in a fixed manner, which then also have to mediate between the different modes of access and the corresponding integrity requirements.

In a particularly advantageous embodiment, it is provided that the termination impedance device is configured as an individual and common termination impedance device. Furthermore, it is provided that the termination impedance device is formed in each case in the region of the main bus device, in particular outside the semiconductor circuit modules. Moreover, it is provided that the termination impedance device is formed in each case between the semiconductor circuit modules and/or directly upstream of the termination contact in the second end region of the main bus device. What is thereby achieved is that the semiconductor circuit modules known in the prior art can be used without the need for modification with regard to the termination impedances in the modules. In this case, for impedance matching, the invention provides an individual and common termination impedance device that, according to the invention, then performs all impedance matchings for the semiconductor circuit configuration.

Another embodiment of the semiconductor circuit configuration according to the invention provides for two impedance states to be formed.

In this case, it is provided that the first impedance state makes it possible to ensure or ensures the signal integrity in the event of a write access to the semiconductor circuit module by the control device.

As an alternative or in addition, it is provided that the second impedance state makes it possible to ensure or ensures the signal integrity in the event of a read access to the semiconductor circuit module by the control device.

In order to realize the impedance matching, it is provided, for example, that the first impedance state corresponds to a first, comparatively low impedance, preferably with a low-value non-reactive resistance. In this case, the low value is deemed to be e.g. a range from 0 Ω to approximately 500 Ω. In this case, the range from 20 Ω to 50 Ω is preferred and the region around about 30 Ω, in particular, is more preferred. A termination in the region around 100 Ω may be advantageous especially in the case of DRAMs as semiconductor circuit modules.

As an alternative or in addition, it is provided that, for further concretization of the impedance matching, the second impedance state corresponds to a second, comparatively high impedance which is greater than the first impedance, the non-reactive resistance being chosen to have a high value, in particular, preferably as an open or interrupted contact-connection. In this context, a high value may be deemed to be, if appropriate, e.g. also the region above approximately 10 kΩ.

In a further embodiment of the semiconductor circuit configuration according to the invention, a plurality of semiconductor circuit modules are provided which, in particular, are configured to act identically or to be of identical type.

The concept according to the invention can be employed particularly advantageously if the semiconductor circuit modules are configured as memory modules, in particular as DIMMs with DRAM, DDR-SDRAM modules and/or the like.

A particularly advantageous embodiment of the semiconductor circuit configuration according to the invention results if the latter is essentially provided on a common main circuit board device and if the termination impedance device is formed on the main circuit board device.

Various embodiments of the termination impedance device are conceivable, in principle. By way of example, by the termination impedance device, in an advantageous form, it is possible to determine whether the control device effects a reading or writing access to the semiconductor circuit modules or the semiconductor circuit module. The corresponding impedance state is correspondingly set automatically after the type of access has been ascertained.

In this case, it is provided that a control line is formed. The control line is connected to the control device by the first end and to a provided control terminal of the termination impedance device by the second end, in order to transmit a control signal—characterizing the access by the control device to the semiconductor circuit module—from the control device to the control terminal of the termination impedance device.

It may be provided, by way of example, that the termination impedance device is essentially formed by an individual transistor that provides the comparatively low impedance or the comparatively low non-reactive resistance in the switched or conducting state via its conduction channel. To that end, it is provided that the termination impedance device has a first transistor device, in particular an n-type MOSFET, that a control terminal, in particular the gate, of the first transistor device forms the control terminal of the termination impedance device, and that an input terminal and an output terminal of the first transistor device, in particular the source terminal and the drain terminal, respectively, are provided as input terminal and as output terminal, respectively, of the termination impedance device in series in the main bus device.

Although, for a low signal on the corresponding control line, that is to say for the datum “0”, the embodiment described last supplies a well-defined and well-switched state with a finite non-reactive resistance. For example for writing by the control device to the respective semiconductor circuit modules, a comparatively well-switchable or switched state with a comparatively high-value resistance—for example for reading by the control device from the respective semiconductor circuit modules—can only be realized with difficulty by the termination impedance device with this individual transistor, because the switching behavior of the n-type MOSFET is comparatively poorer for a high signal, that is to say for the datum “1”.

In accordance with a further embodiment of the semiconductor circuit configuration according to the invention, it is provided that the termination impedance device has a second transistor device, in particular a p-type MOSFET. The input terminal and the output terminal of the second transistor device, in particular the source terminal and the drain terminal, respectively, are directly connected to the input terminal and the output terminal, respectively, of the first transistor device. Furthermore, it is provided that the control terminal of the second transistor device, in particular the gate terminal, is connected to the control terminal of the first transistor device with interposition of an inverter.

What is achieved by this measure is that the correct impedance values are provided by the termination impedance device both for a writing access and for a reading access, namely a finite impedance in the case of writing and, in the case of reading from the semiconductor circuit modules, a comparatively high or high-resistance impedance which ideally tends toward the value infinity.

The p-type MOSFET, together with the inverter, has a good and well-defined switching behavior for the high signal, that is to say for the datum “1”.

Due to the rising transmission rates in the memory bus systems, e.g. between a memory module as the semiconductor circuit module and a controller chip as the control device, it is becoming more and more difficult to ensure the quality of the signals at the receiver. Thus, e.g. a DDR-DRAM system (double data rate) constructed according to SSTL (stub series transistor logic) suffices to ensure a data transmission rate of 266 MT/s (megatransfers per second). In the DDRII specification the data rate is now increased to 400, 533, 600 or 667 MT/s. This is no longer possible with the bus system used hitherto in DDR, since the signal quality at the receiver is insufficient for reliably identifying a datum under all circumstances.

For a write access, the controller drives the signals (data, commands and address) onto the memory bus. At the T points or contact nodes, the data are distributed to the DRAMs and run to the end of the memory bus. In order to avoid a reflection of the waves or signals here, the bus is terminated by a terminating resistance Rterm with respect to a terminating voltage VTT.

For a read access, the DRAM drives the data (e.g. from a slot 1) onto the memory bus, and the signals move in the direction of the controller or control device and the end of the memory bus. The data are received at the controller and the wave is terminated again at the end of the memory bus.

On account of the different topologies seen by a driver during the read or write operations, a determination of the variable values of such a system (driver Ron, serial resistance upstream of the DRAM, impedance of the interconnects, Rterm, VTT) is always an attempt to optimize both operations. However, what is beneficial to a write process has an adverse effect on read operations, and vice versa.

The invention attempts to increase the signal quality by producing a termination e.g. directly on the controller and on the DRAMs, which have a switchable terminating resistance (open and different terminating values). However, this affects the size of the DRAMs/controllers and brings about an increased power consumption on the DRAMs, which already at the present time are operating at the limit of thermal loading.

A further improvement in the signal quality is achieved according to the invention by the termination on the main circuit board or the motherboard being made switchable, to be precise independently of the type of modules. This can be achieved e.g. by using a FET switch instead of fixed SMD resistors. The switch contains a FET transistor that has a specific resistance in the on state.

If the hitherto customary SMD resistors of approximately 20-50 Ω are replaced by a corresponding FET switch, the termination can be switched on for write and off for read, under the control of the controller. If this technology is combined e.g. with an active termination on the controller, it is possible to achieve a separate optimization of the termination between the read and write operations.

By virtue of the terminations at the controller and at the end of the system bus, it is possible to optimize write and read operations separately from one another.

There are conditions that are applicable to both cases, such as, for example, line impedance on the motherboard and on the memory module, resistance to the serial termination on the data lines. However, on the basis of Ron, type of termination and value, it is possible to perform a separate optimization of read and write operations.

Other features which are considered as characteristic for the invention are set forth in the appended claims.

Although the invention is illustrated and described herein as embodied in a semiconductor circuit configuration, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block circuit diagram of an embodiment of a semiconductor circuit configuration according to the invention; and

FIGS. 2 and 3 are circuit diagrams of two embodiments for a termination impedance device.

### DESCRIPTION OF THE PREFERRED EMBODIMENTS

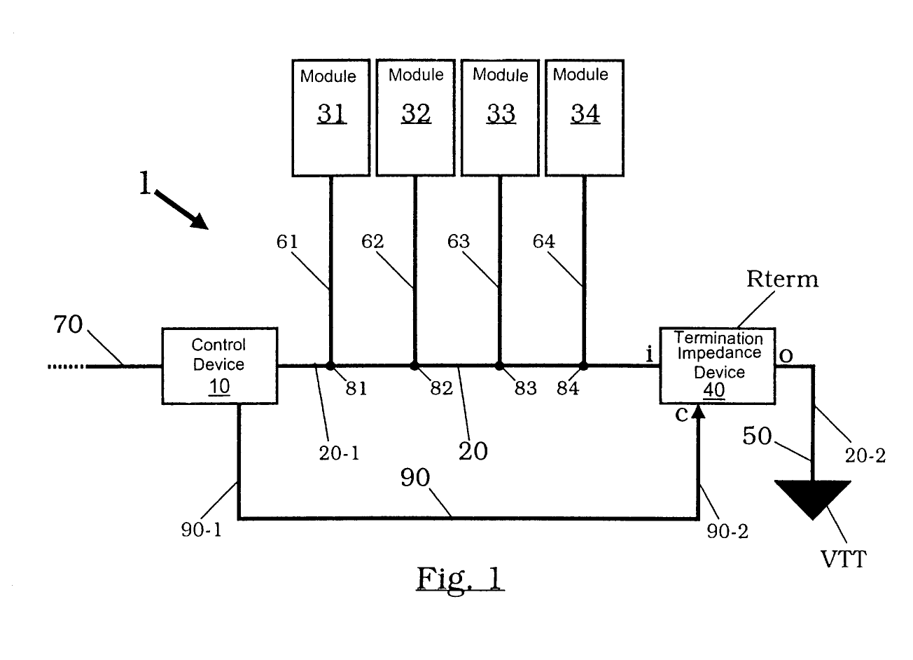

In all the figures of the drawing, sub-features and integral parts that correspond to one another bear the same reference symbol in each case. Referring now to the figures of the drawing in detail and first, particularly, to FIGS. 1 thereof, there is shown a first embodiment of a semiconductor circuit configuration 1 according to the invention in the form of a schematic block diagram.

The semiconductor circuit configuration 1 has a control device 10, to which a main bus device 20 and also a control line device 90 are provided. Externally, the control device 10 receives inquiries and, if appropriate, data via a corresponding access line device 70.

The main bus device 20 has a first end 20-1 and a second end 20-2. The first end 20-1 of the main bus device 20 is connected to the control device 10, whereas the second end 20-2 is connected to a termination contact 50 and, via the latter, to a termination potential VTT. Access line devices 61 to 64 are connected in parallel with the main bus device 20 via contact points 81 to 84, which, for their part, connect the semiconductor circuit modules 31 to 34 provided to the main bus device 20.

The termination impedance device 40, which is switchable between different impedance states, is formed in the second end region 20-2 of the main bus device 20, to be precise in direct proximity to the termination contact 50 and the termination potential VTT connected thereto. In this case, an input terminal i and an output terminal o of the termination impedance device 40 are integrated in series into the main bus device 20. A second end 90-2 of the control line device 90 is connected to a control input c of the termination impedance device 40, whereas the first end 90-1 of the control line device 90 is in turn connected to the control device 10.

During operation, with reading or writing access by the control device 10 to the connected semiconductor circuit modules 31 to 34, a corresponding control signal is output to the termination impedance device 40 via the control line device 90. The termination impedance device 40 provides a finite termination resistance Rterm, in the case of writing, in reaction to a control signal fed via the control line device 90. By contrast, the termination resistance Rterm is switched to a high value in the case of a read access.

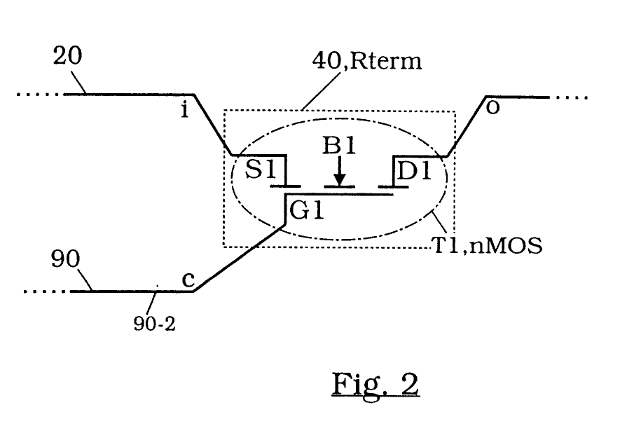

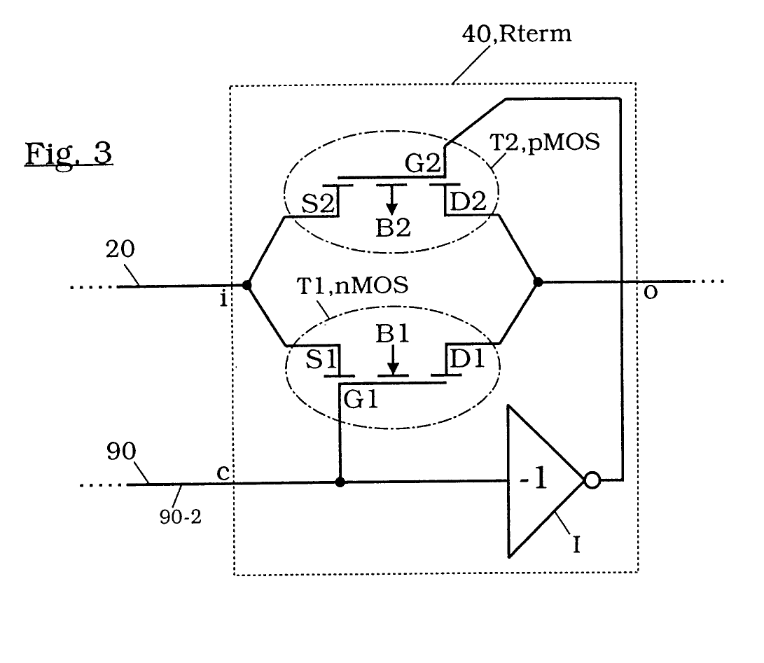

FIGS. 2 and 3 show, in schematic form, two exemplary embodiments of the switchable termination impedance device 40 provided according to the invention.

The embodiment of FIG. 2 contains an individual n-type MOSFET T1, whose source terminal S1 forms the input terminal i and whose drain terminal D1 forms the output terminal o of the termination impedance device 40. The second end 90-2 of the control line device 90 is connected to a gate terminal G1 of the first transistor device T1, thereby forming the control terminal c of the termination impedance device 40 of the first embodiment of FIG. 2.

In the embodiment of FIG. 3 for the termination impedance device 40 provided according to the invention, over and above the provision of the first transistor device T1 in the form of an n-type MOSFET, a second transistor device T2 is formed, in particular in the form of a p-type MOSFET.

A source region S2 of the second transistor device T2, together with the source region S1 of the first transistor device T1, forms the input terminal i of the termination impedance device 40. A drain region D2 of the second transistor device T2, together with the drain terminal D1 of the first transistor device T1, correspondingly forms the output terminal o of the termination impedance device 40 according to the invention. The gate terminals G1 and G2 are jointly driven by the control signal fed via the control line device 90, the gate terminal G1 of the first transistor device T1 being connected to the gate terminal G2 of the second transistor device T2 with interposition of an inverter I.

During the operation of the embodiment of FIG. 3, in the case of a write access, the first transistor device T1 provides a finite resistance as the termination impedance, in particular in the region of about 30 Ω. In the reading state, by contrast, an open termination in the sense of a high-resistance impedance or a high-value termination resistance is essentially provided.

I claim:

1. A semiconductor circuit configuration, comprising:
at least one semiconductor circuit module;
a control device for accessing said semiconductor circuit module;
a termination contact;
a main bus connected to said semiconductor circuit module device and having a first end region connected to said control device and a second end region connected to a termination potential through said termination contact; and
at least one termination impedance device for impedance matching with regard to an access by said control device to said semiconductor circuit module, said termination impedance device being switchable between a plurality of impedance states, said termination impedance device determining whether said control device effects a read access or a write access to said semiconductor circuit module and automatically sets an impedance state.

2. The semiconductor circuit configuration according to claim 1, wherein said termination impedance device is an individual and common impedance device disposed outside of said semiconductor circuit module and disposed in said main bus device.

3. The semiconductor circuit configuration according to claim 1, wherein said termination impedance device has two impedance states including a first impedance state and a second impedance state.

4. The semiconductor circuit configuration according to claim 3, wherein the first impedance state makes it possible to ensure signal integrity in an event of the write access to said semiconductor circuit module by said control device.

5. The semiconductor circuit configuration according to claim 4, wherein the second impedance state makes it possible to ensure the signal integrity in an event of the read access to said semiconductor circuit module by said control device.

6. The semiconductor circuit configuration according to claim 5, wherein the first impedance state corresponds to a comparatively low first impedance.

7. The semiconductor circuit configuration according to claim 6, wherein the second impedance state corresponds to a high second impedance which is greater than the first impedance, and being a non-reactive resistance.

8. The semiconductor circuit configuration according to claim 1, wherein said semiconductor circuit module is one of a plurality of semiconductor circuit modules and said semiconductor circuit modules are identical to each other.

9. The semiconductor circuit configuration according to claim 8, wherein said semiconductor circuit modules are memory modules.

10. The semiconductor circuit configuration according to claim 1, further comprising a common main circuit board device, and said termination impedance device is disposed on said common main circuit board device.

11. The semiconductor circuit configuration according to claim 1, further comprising a control line having a first end connected to said control device and a second end, said termination impedance device having a control terminal connected to said second end of said control line, said control line transmitting a control signal from said control device to said control terminal of said termination impedance device, the control signal characterizing the access by said control device to said semiconductor circuit module.

12. The semiconductor circuit configuration according to claim 11, wherein:
said termination impedance device has an input terminal, an output terminal, and a transistor device, said transistor device having a control terminal forming said control terminal of said termination impedance device, said transistor device further having an input terminal and an output terminal functioning as said input terminal and as said output terminal, respectively, of said termination impedance device and disposed in series in said main bus device.

13. The semiconductor circuit configuration according to claim 12,
further comprising an inverter; and
wherein said termination impedance device contains a further transistor device having an input terminal and an output terminal directly connected to said input terminal and said output terminal, respectively, of said transistor device, and said further transistor device further having a control terminal connected to said control terminal of said transistor device with an interposition of said inverter.

14. The semiconductor circuit configuration according to claim 2, wherein said termination impedance device is disposed directly upstream of said termination contact in said second end region of said main bus device.

15. The semiconductor circuit configuration according to claim 2, wherein said semiconductor circuit module is one of a plurality of semiconductor circuit modules and said termination impedance device is disposed between said semiconductor circuit modules in said main bus device.

16. The semiconductor circuit configuration according to claim 6, wherein the comparatively low first impedance is a low-value non-reactive resistance.

17. The semiconductor circuit configuration according to claim 16, wherein the low-value non-reactive resistance is in a range from 0 Ω to approximately 500 Ω.

18. The semiconductor circuit configuration according to claim 16, wherein the low-value non-reactive resistance is in a range from 20 Ω to approximately 50 Ω.

19. The semiconductor circuit configuration according to claim 16, wherein the low-value non-reactive resistance is approximately 30 Ω.

20. The semiconductor circuit configuration according to claim 12, wherein:
said transistor device is a n-type MOSFET;
said control terminal is a gate of said transistor device;
said input terminal of said transistor device is a source terminal; and
said output terminal of said transistor device is a drain terminal.

21. The semiconductor circuit configuration according to claim 13, wherein:
said further transistor device is a p-type MOSFET;
said input terminal and said output terminal of said further transistor device are a source terminal and a drain terminal, respectively; and
said control terminal of said further transistor device is a gate terminal.

22. The semiconductor circuit configuration according to claim 9, wherein said memory modules are DIMMs with one of DRAM modules and DDR-SDRAM modules.
